(19) United States
(12) Patent Application Publication
(10) Pub. No.: US 2026/0337814 A1
(43) Pub. Date: Oct. 29, 2026

(54) APPARATUS FOR PRODUCING GROUP III COMPOUND SEMICONDUCTOR CRYSTAL

(71) Applicant: Panasonic Holdings Corporation, Kadoma-shi (JP)

(72) Inventors: Yunosuke OSUGI, Osaka (JP); Masayuki HOTEIDA, Osaka (JP); Junichi TAKINO, Osaka (JP); Shunichi MATSUNO, Kyoto (JP)

(21) Appl. No.: 19/633,230

(22) Filed: Mar. 30, 2026

(30) Foreign Application Priority Data
Apr. 1, 2025 (JP) 2025-060287

(51) Int. Cl. C30B 25/10; C30B 29/16; C30B 29/40

(52) U.S. Cl. CPC C30B 25/10; C30B 29/16; C30B 29/406

(57) ABSTRACT

A Group III compound semiconductor crystal producing apparatus for producing a Group III compound semiconductor crystal, includes a reaction vessel, wherein the reaction vessel comprises: a heating section that heats the reaction vessel; a thermal insulation section that thermally insulates the heating section from the outside; and a power-feeding section that supplies power to the heating section, wherein the thermal insulation section includes a first thermal insulator arranged to surround an outer periphery of the heating section, wherein the power-feeding section includes: a power-feeding rod disposed inside a first through-hole of the first thermal insulator that opens toward the heating section, the first through-hole being defined by through-hole walls of the first thermal insulator; an insulating cover for the power-feeding rod disposed surrounding the power-feeding rod; and a support for supporting the power-feeding rod disposed outside the first thermal insulator and physically supporting the power-feeding rod, and wherein the insulating cover has a first gap between the insulating cover and the power-feeding rod, and a second gap between the insulating cover and the first through-hole of the first thermal insulator, the first gap being opened toward the support of the power-feeding section, and the second gap being defined along the first through-hole.

### CROSS REFERENCE TO RELATED APPLICATION

This application claims a priority of Japanese Patent Application No. 2025-60287 filed on Apr. 1, 2025, the content of which is incorporated herein by reference.

### BACKGROUND OF THE INVENTION

### 1. Field of the Invention

The present disclosure relates to a Group III compound semiconductor crystal producing apparatus for producing a Group III compound semiconductor crystal. In particular, the disclosure relates to a Group III compound semiconductor crystal producing apparatus that supplies gas to a substrate to be processed placed in a reaction chamber and that vapor-phase grows a Group III compound semiconductor crystal on the substrate to be processed.

### 2. Description of the Related Art

Group III compound semiconductors such as GaN, AlGaN, InGaN, and Ga₂O are used in fields such as optical devices such as light-emitting diodes and semiconductor lasers, and heterojunction high-speed electronic devices. One method for producing GaN, a Group III compound semiconductor, is a hydride vapor phase epitaxy (HVPE) method, which is in practical use, in which a Group III element metal (e.g., Ga metal) is reacted with a chloride gas (e.g., HCl gas) to generate a Group III element metal chloride gas (GaCl gas), and in which GaN is grown using the Group III element metal chloride gas and a nitrogen-containing gas (e.g., NH₃ gas) (see, for example, JP S52-23600 A).

However, the HVPE method has a problem that a large amount of NH₄Cl (ammonium chloride) is generated as a by-product during crystal growth, which may clog the exhaust piping of the producing apparatus, thus inhibiting crystal growth. To solve this problem, an oxygen vapor phase epitaxy (OVPE) has been proposed, in which a Group III element metal (e.g., gallium metal) is reacted with an oxidizer (e.g., H₂O gas) to generate a Group III element metal oxide gas (Ga₂O gas), and in which GaN is grown using the Group III element metal oxide gas and a nitrogen-containing gas (e.g., NH₃ gas) (see, e.g., WO 2015/053341).

A feature of the HVPE and OVPE methods is that they can achieve extremely high growth rates of 10 μm/h or more, or even 100 μm/h or more, compared to the typical growth rate of approx. 1 μm/h achieved by other crystal growth methods such as metalorganic chemical vapor deposition (MOCVD) and molecular beam epitaxy (MBE). For this reason, they are used to produce a GaN free-standing substrate.

FIG. 10 is a schematic cross-sectional view showing the cross-sectional structure of a power-feeding section used in a conventional Group III compound semiconductor crystal producing apparatus. Power-feeding rods 33 and 34 pass through first through-holes 18 disposed in a first thermal insulator 30 for retaining heat generated by a first heater 14 and a second heater 15 inside, and are connected to a connection section 40 and the first heater 14 and the second heater 15. Because the first thermal insulator 30 is formed of an electrically conductive material, contact between the power-feeding rods 33 and 34 and the first thermal insulator 30 could result in current leakage to the entire apparatus via the first thermal insulator 30. Therefore, to prevent current leakage, the power-feeding rods 33 and 34 are covered with a insulating cover 36.

The first and second heaters 14 and 15 of the prior art example are covered with a thermal insulation section for heat retention purposes, and are externally powered by the power-feeding rods 33 and 34 inserted into the first through-holes 18 of the first thermal insulator 30. Because a raw-material reaction section 5 and a raw-material container 3 reach temperatures of 1000 °C or higher, the thermal insulation section is constituted by an electrically conductive member using carbon. Therefore, to prevent electrical leakage to the entire apparatus via the first thermal insulator 30, the power-feeding rods 33 and 34 are covered with the insulating cover 36. However, reactive gas leaking from a raw-material reaction chamber 2 through gaps due to the assembly structure of the apparatus reacts with the carbon in the thermal insulation section, generating carbide. Generated carbide 101 flows from the outside of the thermal insulation section into the first through-holes 18 of the first thermal insulator 30 and adheres to the surface of the insulating cover 36. The carbon coating layer (carbide layer) 101 adhered to the surface of this insulating cover 36 forms a current path 102 from the power-feeding rods 33 and 34 to the first thermal insulator 30, and is a cause of current leakage to the first thermal insulator 30.

### SUMMARY

The present disclosure is intended to solve the above-mentioned problems, and one non-limiting and exemplary embodiments provides a Group III compound semiconductor crystal producing apparatus that can suppress current leakage from power-feeding rods and that enables safe and smooth production.

In one general aspect, the techniques disclosed here feature: a Group III compound semiconductor crystal producing apparatus for producing a Group III compound semiconductor crystal, comprising a reaction vessel,
wherein the reaction vessel comprises:
   a heating section that heats the reaction vessel;
   a thermal insulation section that thermally insulates the heating section from the outside; and
   a power-feeding section that supplies power to the heating section,
wherein the thermal insulation section includes a first thermal insulator arranged to surround an outer periphery of the heating section,
wherein the power-feeding section includes:
   a power-feeding rod disposed inside a first through-hole of the first thermal insulator that opens toward the heating section, the first through-hole being defined by through-hole walls of the first thermal insulator;
   an insulating cover for the power-feeding rod disposed surrounding the power-feeding rod; and
   a support for supporting the power-feeding rod disposed outside the first thermal insulator and physically supporting the power-feeding rod, and
wherein the insulating cover has a first gap between the insulating cover and the power-feeding rod, and a second gap between the insulating cover and the first through-hole of the first thermal insulator,
the first gap being opened toward the support of the power-feeding section, and
the second gap being defined along the first through-hole.

According to the Group III compound semiconductor crystal producing apparatus according to the present disclosure, the first gap is disposed between the insulating cover and the power-feeding rod, thereby making it possible to suppress current leakage from the power-feeding rod.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a schematic cross-sectional view showing an example of the cross-sectional configuration of a Group III compound semiconductor crystal producing apparatus according to a first embodiment of the present disclosure;

FIG. 2A is a front cross-sectional view showing an example of the arrangement of a source gas nozzle and reactive gas nozzles in the Group III compound semiconductor crystal producing apparatus of FIG. 1;

FIG. 2B is a top view showing an example of the arrangement of the source gas nozzle and the reactive gas nozzles in the Group III compound semiconductor crystal producing apparatus of FIG. 1;

FIG. 3 is a schematic cross-sectional view showing the cross-sectional structure of a power-feeding section in the Group III compound semiconductor crystal producing apparatus of FIG. 1;

FIG. 4 is a graph showing the relationship between the accumulated film thickness of carbide adhered to the surface of an insulating cover and the secondary leakage current, depending on whether or not there is a gap between the power-feeding rod and the insulating cover;

FIG. 5 is a schematic cross-sectional view showing the cross-sectional structure of a power-feeding section in a Group III compound semiconductor crystal producing apparatus according to a second embodiment;

FIGS. 6A and 6B are diagrams showing the difference in the adhesion of carbide to the insulating cover when the flow velocity, obtained by subtracting the flow velocity of carbide-containing gas flowing from the support for supporting the power-feeding rod into the first through-hole from the flow velocity of inert gas, is 2.0 m/s (a) and 0.5 m/s (b);

FIG. 7A is a schematic cross-sectional view showing the cross-sectional structure of a power-feeding section in a Group III compound semiconductor crystal producing apparatus according to a third embodiment, FIG. 7B is a schematic cross-sectional view taken along line A-A in FIG. 7A, and FIG. 7C is a schematic cross-sectional view taken along line B-B in FIG. 7A;

FIG. 8 is a schematic cross-sectional view showing an example of the configuration of a support for supporting the power-feeding rod in a Group III compound semiconductor crystal producing apparatus according to a fourth embodiment;

FIG. 9A is a schematic cross-sectional view showing the state where a first heater has expanded and moved vertically upward in the Group III compound semiconductor crystal producing apparatus of FIG. 8;

FIG. 9B is a schematic cross-sectional view showing the state where a supporting column has expanded and moved vertically upward in the Group III compound semiconductor crystal producing apparatus of FIG. 8; and

FIG. 10 is a schematic cross-sectional view showing the cross-sectional structure of a power-feeding section in a conventional Group III compound semiconductor crystal producing apparatus.

### DETAILED DESCRIPTION

A Group III compound semiconductor crystal producing apparatus for producing a Group III compound semiconductor crystal according to a first aspect, includes a reaction vessel,
wherein the reaction vessel comprises:
   a heating section that heats the reaction vessel;
   a thermal insulation section that thermally insulates the heating section from the outside; and
   a power-feeding section that supplies power to the heating section,
wherein the thermal insulation section includes a first thermal insulator arranged to surround an outer periphery of the heating section,
wherein the power-feeding section includes:
   a power-feeding rod disposed inside a first through-hole of the first thermal insulator that opens toward the heating section, the first through-hole being defined by through-hole walls of the first thermal insulator;
   an insulating cover for the power-feeding rod disposed surrounding the power-feeding rod; and
   a support for supporting the power-feeding rod disposed outside the first thermal insulator and physically supporting the power-feeding rod, and
wherein the insulating cover has a first gap between the insulating cover and the power-feeding rod, and a second gap between the insulating cover and the first through-hole of the first thermal insulator,
the first gap being opened toward the support of the power-feeding section, and
the second gap being defined along the first through-hole.

The Group III compound semiconductor crystal producing apparatus according to a second aspect in addition to the first aspect, the second gap may allow inert gas to flow from the heating section toward the support.

The Group III compound semiconductor crystal producing apparatus according to a third aspect in addition to the first or second aspect, the support for supporting the power-feeding rod may include:
a connection section physically connected to the power-feeding rod;
an electrical insulation section supporting the connection section; and
a supporting column fixing the electrical insulation section,
wherein the connection section may include a stopper that is slidable in a second through-hole disposed in the electrical insulation section,
wherein the stopper may have:
a center part that is slidable along the second through-hole disposed in the electrical insulation section, and
upper and lower tabs provided at both ends of the center part, each having a cross section greater than the cross section of the second through-hole at the top opening and bottom opening of the second through-hole so as to define a range in which the stopper slides through the second through-hole, and
wherein the stopper may have a third gap between the lower tab and an undersurface of the electrical insulation section around the bottom opening, and a fourth gap between the upper tab and an upper surface of the electrical insulation section around the top opening.

The Group III compound semiconductor crystal producing apparatus according to a fourth aspect in addition to any one of the first to third aspects, further includes:
a plurality of flow channels through which inert gas is flowable from a side surface of the insulating cover to the first gap between the insulating cover and the power-feeding rod.

A Group III compound semiconductor crystal producing apparatus according to an embodiment of the present disclosure will be described with reference to the accompanying drawings, in which substantially identical components are designated by the same reference numerals.

### First Embodiment

### Group III Compound Semiconductor Crystal Producing Apparatus

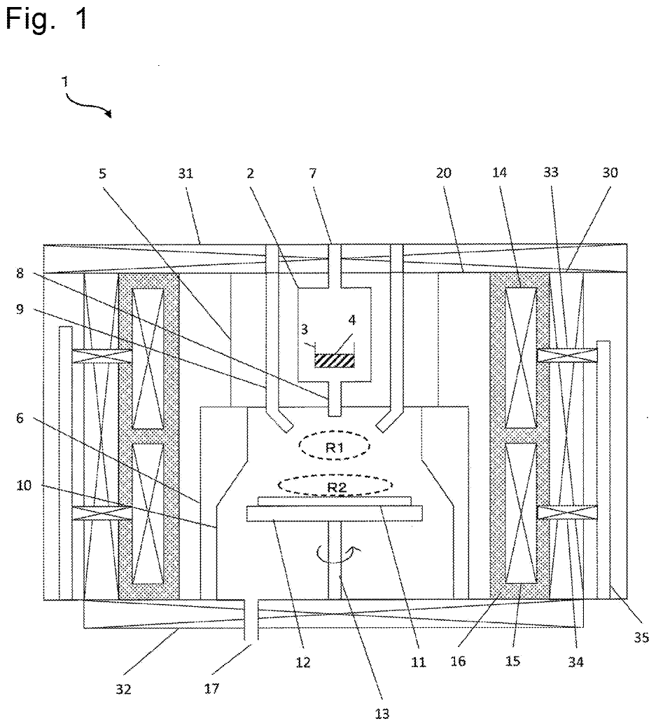

Hereinafter, a first embodiment of the present disclosure will be described with reference to FIG. 1. FIG. 1 is a schematic cross-sectional view showing an example of the cross-sectional configuration of a Group III compound semiconductor crystal producing apparatus 1 according to the first embodiment of the present disclosure. Note that the size, ratio, etc. of each component in FIG. 1 may differ from the actual size, ratio, etc.

The Group III compound semiconductor crystal producing apparatus 1 according to the first embodiment shown in FIG. 1 is a vapor phase growth apparatus and includes a reaction vessel 20 for growing a Group III compound semiconductor crystal. The reaction vessel 20 may have, for example, a cylindrical shape extending vertically, and includes the source reaction section 5 for generating a Group III element-containing gas, a crystal growth section 6, and a gas flow channel 10. A Group III element-containing gas is generated in a source reaction section 3 provided within the source reaction section 5. The generated Group III element-containing gas is delivered by a source gas nozzle 8 and injected toward the crystal growth section 6. In the crystal growth section 6, the Group III element-containing gas injected by the source gas nozzle 8 and the reactive gas introduced by a reactive gas nozzle 9 are mixed in a mixing region R1 and then react in a crystal growth region R2 on a seed substrate 11, thereby growing a Group III compound semiconductor crystal on the seed substrate 11.

In order to maintain constant temperatures in the source reaction section 5 and the crystal growth section 6, a heating section 16 for heating the reaction vessel 20 is installed around the outer periphery of the reaction vessel 20. The source gases, including the unreacted Group III element-containing gas and the reactive gas, and carrier gases such as H₂ and N₂ are discharged from a discharge port 17 disposed downstream of the seed substrate 11.

The constituent members of the Group III compound semiconductor crystal producing apparatus 1 according to the first embodiment shown in FIG. 1 will be described in detail below.

### Source Reaction Section

The source reaction section 5 includes the source reaction chamber 2 and the source gas nozzle 8, and has a cylindrical shape in this embodiment. In the source reaction section 5, Group III element-containing gas is generated.

### Source Reaction Chamber

The source vessel 3 containing a starting Ga source 4, which is a Group III element-containing source, is disposed within the source reaction chamber 2. The source reaction chamber 2 is also connected to a reactive gas supply pipe 7, through which a reactive gas that reacts with the starting Ga source 4 is introduced. The interior of the source reaction chamber 2 is maintained at a desired temperature by the first heater 14 of the heating section 16. Preferably, the starting Ga source 4 reacts with the reactive gas in the source reaction chamber 2, which is maintained at a temperature of 900 °C or higher and 1300 °C or lower by heating with the first heater 14, to generate Group III element-containing gas.

Here, methods for generating Group III element-containing gas include a method of oxidizing a Group III element-containing source and a method of reducing a Group III element-containing source.

As a method for oxidizing a Group III element-containing source, a reaction system will be described in which metallic Ga is used as the starting Ga source 4 and H₂O gas, an oxidizing gas, is used as the reactive gas. In this case, as shown in the following formula (1), introduced H₂O gas reacts with metallic Ga under heating to generate Ga₂O gas that is Group III element-containing gas.

2Ga+H₂O→Ga₂O+H₂ 1

In addition to Ga, Al, In, etc. can also be used as the Group III element source. In any case, Group III oxide gas is produced.

Next, a reaction system will be described for a method of reducing a Group III element-containing source, in which Ga₂O₃ is used as the starting Ga source 4 and H₂ gas, a reducing gas, is used as the reactive gas. As shown in the following formula (2), in a heated state, introduced H₂ gas reacts with Ga₂O₃ to generate Ga₂O gas that is a Group III element-containing gas.

Ga₂O₃+2H₂→Ga₂O+2H₂O 2

As the Group III element-containing source, in addition to Ga₂O₃, Al₂O₃ or In₂O₃ can also be used. In either case, a Group III oxide gas is generated.

As a carrier gas for the oxidizing gas or reducing gas, inert gas such as Ar or N₂, or H₂ gas can be used.

### Source Gas Nozzle

The Group III element-containing gas, e.g., Ga₂O gas, generated in the source reaction chamber 2 is introduced through the source gas nozzle 8 disposed downstream of the source reaction section 5 and injected toward the crystal growth section 6. To prevent deposits of Group III compound semiconductor crystals from adhering to the inner wall surface of the producing apparatus 1, the source gas nozzle 8 preferably has a separation gas outlet formed on its inner or outer periphery. The separation gas may be, but is not limited to, an inert gas such as Ar or N₂, or H₂ gas. The inner diameter of the source gas nozzle 8 is preferably, but is not limited to, a range of more than 0 mm and not more than 100 mm, more preferably, 20 mm or more and not more than 60 mm. The wall thickness of the source gas nozzle 8 is also not limited to, but is preferably, but not limited to, 0.5 mm or more and not more than 10 mm, more preferably, 1 mm or more and not more than 3 mm.

### Crystal Growth Section

The crystal growth section 6 includes a substrate holding member 12 and the reactive gas nozzle 9, and has a cylindrical shape in this embodiment. In the crystal growth section 6, a Group III element-containing gas reacts with a reactive gas (such as a nitrogen-containing gas or an oxygen-containing gas), and a Group III compound semiconductor crystal grows on the seed substrate 11.

### Substrate Holding Member

The substrate holding member 12 may be, for example, a substrate susceptor. The seed substrate 11 is held on the upper surface 12a of the substrate holding member 12. The shape of the substrate holding member 12 is not particularly limited, but it is preferable that the substrate holding member 12 does not have a structure that inhibits crystal growth. For example, if a structure that may lead to crystal growth is present near the crystal growth surface of the seed substrate 11, a circulating flow will be generated, and deposits will adhere thereto, thereby deteriorating the uniformity of the Group III compound semiconductor crystal film on the seed substrate 11. In this embodiment, the seed substrate 11 and the substrate holding member 12 are circular. Examples of materials that can be used for the substrate holding member 12 include ceramics such as carbon, SiC-coated carbon, PG-coated carbon, PBN-coated carbon, and SiC, as well as molybdenum, iron, cobalt, nickel, and alloys containing these as main components.

Furthermore, the substrate holding member 12 is connected to a rotating shaft 13, and the rotating shaft 13 allows the substrate holding member 12 to rotate the seed substrate 11 during the growth of the Group III compound semiconductor crystal. The rotating shaft 13 preferably has a mechanism capable of controlling the rotation up to 3000 rpm.

### Reactive Gas Nozzle

The reactive gas nozzle 9 injects a reactive gas (such as a nitrogen-containing gas or an oxygen-containing gas) toward the seed substrate 11 to react with the Group III element-containing gas to produce a Group III compound semiconductor crystal. In the Group III compound semiconductor crystal producing apparatus 1 shown in FIG. 1, at least two reactive gas nozzles 9 are disposed, and the two or more reactive gas nozzles 9 may be arranged, for example, radially with respect to the center of the substrate holding member 12, although this arrangement is not particularly limited. In order to improve the mixing efficiency of the Group III element-containing gas injected from the source gas nozzle 8 and the reactive gas injected from the reactive gas nozzle 9, the injection direction of the reactive gas nozzle 9 preferably intersects with the injection direction of the source gas nozzle 8 just before the upstream side of the seed substrate 11, when viewed from the front and from above with respect to the upper surface 12a of the substrate holding member 12.

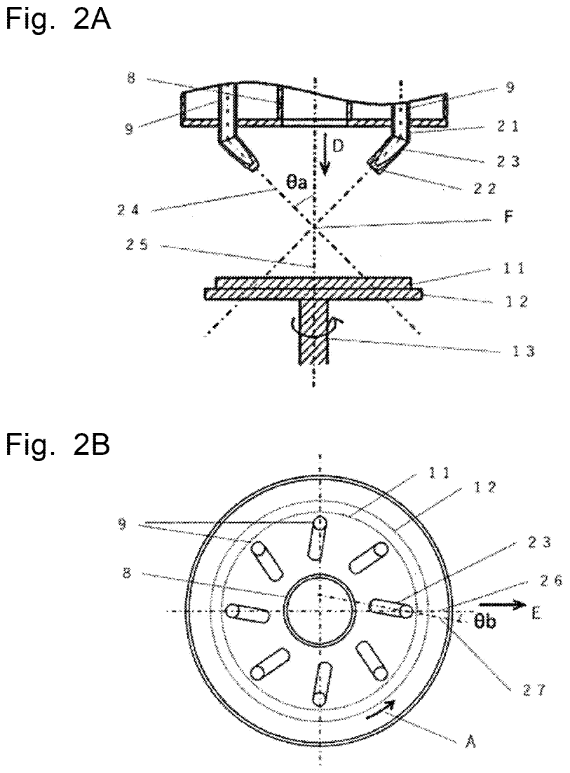

FIG. 2A is a front cross-sectional view showing an example of the arrangement of the source gas nozzle and the reactive gas nozzle in the Group III compound semiconductor crystal producing apparatus 1 of FIG. 1. FIG. 2B is a top view showing an example of the arrangement of the source gas nozzle and the reactive gas nozzle in the Group III compound semiconductor crystal producing apparatus 1 of FIG. 1. As shown in FIG. 2A, the source gas nozzle 8 is arranged along a linear direction D, with the injection direction of the injection port facing the upper surface 12a of the substrate holding member. The reactive gas nozzle 9 includes a main body 21 and a tip portion 23 having an injection port 22. The tip portion 23 is inclined at an inclination angle θa with respect to the direction D. That is, in the front view of FIG. 2A, an imaginary line 24 along the injection direction of the reactive gas nozzle 9 and an imaginary line 25 along the injection direction of the source gas nozzle 8 intersect at a position F above the substrate holding member 12. The inclination angle θa is the angle formed by the injection directions of the source gas nozzle 8 and the reactive gas nozzle 9 in a plane vertical to the upper surface 12a of the substrate holding member.

Next, as shown in FIG. 2B, the Group III compound semiconductor crystal producing apparatus 1 includes at least two reactive gas nozzles 9. In this embodiment, the at least two reactive gas nozzles 9 are arranged radially about the center of the substrate holding member 12, as shown in the top view of FIG. 2B. The tip 23 of the reactive gas nozzle 9 is inclined at a deflection angle θb with respect to the radial direction E indicated by the arrow on the top surface 12a of the substrate holding member. That is, the deflection angle θ b is the angle formed between the tip 23 of the reactive gas nozzle 9 and the radial direction of the seed substrate 11, as shown in the top view of FIG. 2B.

In this embodiment, each reactive gas nozzle 9 is arranged so that when it self-rotates by the deflection angle θb in the forward direction of the rotation direction A of the substrate holding member 12 as viewed from above in FIG. 2B, it becomes radially directed on the upper surface 12a of the substrate holding member. This allows the reactive gas ejected from the plural reactive gas nozzles 9 to form a swirling flow, thereby improving the mixing efficiency with the Group III element-containing gas. Note that the ejection direction of the plural reactive gas nozzles 9 is not limited to this, and the plural reactive gas nozzles 9 may be arranged so as to be deflected in the direction opposite to the direction shown in FIG. 2B.

In the crystal growth section 6, for example, a Group III compound semiconductor crystal such as GaN or Ga₂O₃ can be grown on the seed substrate 11. When growing a GaN crystal, a nitrogen-containing gas such as NH₃ gas, NO gas, NO₂ gas, N₂H₂ gas, or N₂H₄ gas can be used. When growing a Ga₂O₃ crystal, an oxygen-containing gas such as O₂ gas or H₂O gas can be used. Similarly to the source gas nozzle 8, the reactive gas nozzle 9 preferably has a separate gas discharge port formed on its inner or outer periphery to prevent deposits of Group III compound semiconductor crystal from adhering to the inner wall surface of the producing apparatus 1. The separate gas can be, but is not particularly limited to, an inert gas such as Ar or N₂, or H₂ gas.

The inner diameter of the reactive gas nozzle 9 is not particularly limited, but is preferably greater than 0 mm and less than 30 mm, more preferably 3 mm or more and 15 mm or less. The inclination angle θa of the reactive gas nozzle 9 is not particularly limited, but is preferably greater than 0 degrees and less than 90 degrees, more preferably in the range of 5 degrees to 60 degrees. The deflection angle θb of the reactive gas nozzle 9 is not particularly limited, but is preferably greater than 0 degrees and less than 90 degrees, more preferably in the range of 5 degrees to 45 degrees.

In order to promote the growth of Group III compound semiconductor crystals in a crystal growth region S2, it is preferable to heat the reactive gas nozzle 9 and decompose the nitrogen-containing gas or oxygen-containing gas in the reactive gas nozzle 9 at a predetermined ratio. In this embodiment, the reactive gas nozzle 9 is heated by the first heater 14 of the heating section 16 disposed on the outer periphery thereof, in the same manner as the source reaction chamber 2 described above.

### Heating Section

The heating section 16 has the first heater 14 and the second heater 15. The first heater 14 is located above the side of the Group III compound semiconductor crystal producing apparatus 1 in order to maintain the interior of the source reaction chamber 2 at a desired temperature. The second heater 15 is located below the side of the Group III compound semiconductor crystal producing apparatus 1 in order to maintain the crystal growth source 6 at a desired temperature. In the first embodiment, the first heater 14 heats to, for example, 900 °C to 1300 °C, and the second heater 15 heats to, for example, 900 °C to 1400 °C. In the first embodiment, the first heater 14 and the second heater 15 are made of carbon. The outer peripheries of the first heater 14 and the second heater 15 are surrounded by the first thermal insulator 30. In order to supply power to the first heater 14 and the second heater 15, the power-feeding rod 33 penetrating the first thermal insulator 30 and connected to the first heater and the second heater is provided.

### Thermal Insulation Section

As shown in FIG. 1, the thermal insulation section is composed of the first thermal insulator 30, a second thermal insulator 31, and a third thermal insulator 32. In this embodiment, the first thermal insulator 30 has a cylindrical shape and is disposed on the outer periphery of the first heater 14 and the second heater 15 of the heating section 16. In this embodiment, the second thermal insulator 31 and the third thermal insulator 32 have a disk shape, with the second thermal insulator 31 closing the upper opening of the first thermal insulator 30 and the third thermal insulator 32 closing the lower opening of the first thermal insulator 30. The first thermal insulator 30 has a first through-hole for passing the power-feeding rod 33 therethrough, the second thermal insulator 31 has a through-hole for passing a reactive gas nozzle 9 and a reactive gas supply pipe 7 therethrough, and the third thermal insulator 32 has a through-hole for passing a discharge port 17 therethrough. The first thermal insulator 30, the second thermal insulator 31, and the third thermal insulator 32 are made of carbon.

### Power-Feeding Section

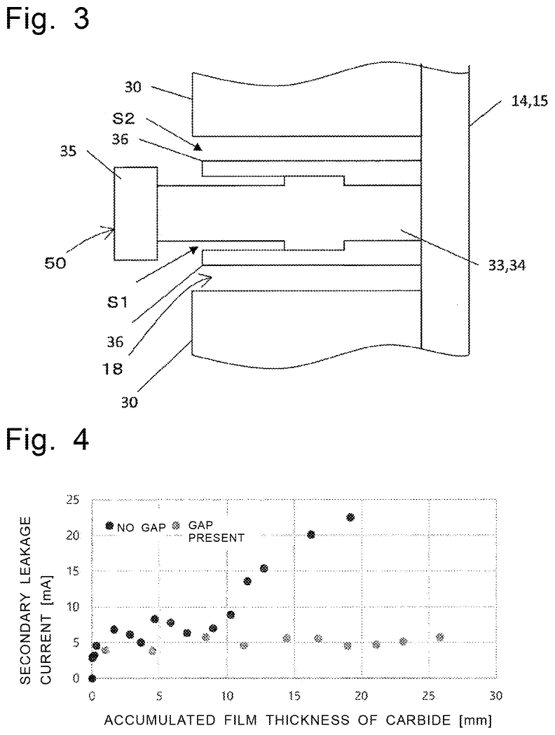

FIG. 3 is a schematic cross-sectional view showing the cross-sectional structure of a power-feeding section 50 in the Group III compound semiconductor crystal producing apparatus 1 of FIG. 1. The power-feeding section 50 includes the power-feeding rod 33, an insulating cover 36 for covering the power-feeding rod 33, and a support 35 for supporting the power-feeding rod 33. In the first embodiment, the power-feeding rod 33 has, for example, a cylindrical shape. The support 35 is disposed so as to cover the outer periphery of the first thermal insulator 30. The power-feeding rods 33 and 34 are connected to the first heater 14 and the second heater 15, respectively, and pass through the first through-hole 18 of the first thermal insulator 30 to be connected to the support 35. The first through-hole 18 is defined by through-hole walls of the first thermal insulator 30. Power is supplied to the first heater 14 and the second heater 15 from outside the apparatus via the power-feeding rod 33.

### Insulating Cover

As shown in FIG. 3, the insulating cover 36 is disposed to cover the power-feeding rod 33. In this embodiment, the power-feeding rod 33 and the insulating cover 36 each have a cylindrical shape. However, this is not limited thereto and the power-feeding rod 33 and the insulating cover 36 may have a rectangular outer periphery and a cylindrical inner periphery. A gap S1 is disposed between the power-feeding rod 33 and the insulating cover 36, and a gap S2 is disposed between the insulating cover 36 and the first thermal insulator 30. Since the gap S1 is open only on the side connected to the support 35, the inner surface of the insulating cover 36 has a stepped structure. This also functions to prevent the insulating cover 36 from slipping off. A protrusion on the inner surface of the insulating cover 36 is clamped between a protrusion on the outer periphery of the power-feeding rod 33 and the first and second heaters 14 and 15, thereby restricting sliding of the insulating cover 36.

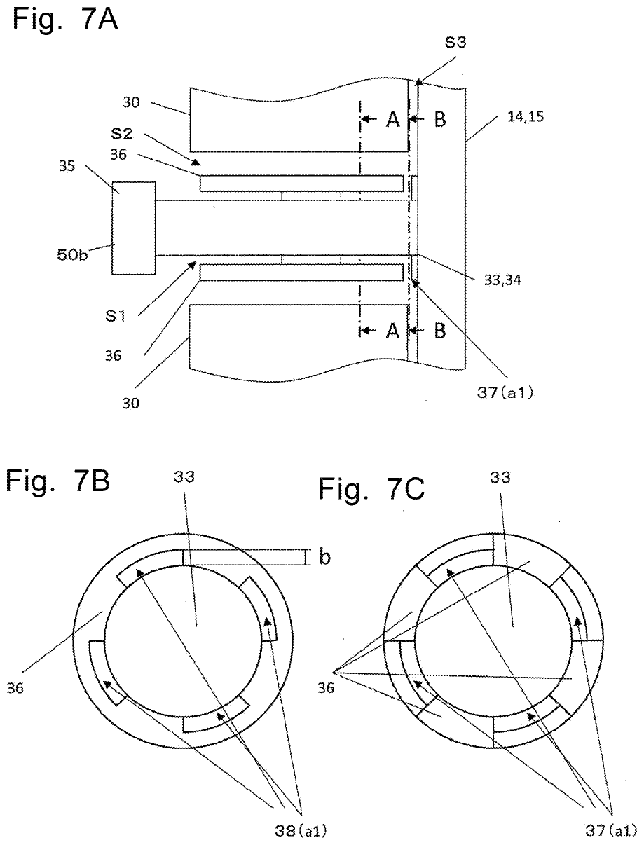

The gap S1 is not particularly limited, but is preferably 0.2 mm or more and 2.5 mm or less, more preferably 0.5 mm or more and 1.5 mm or less. The depth of the gap S1 is 30 mm or more and 40 mm or less, more preferably 33 mm or more and 37 mm or less. The gap S2 is not particularly limited, but is preferably 2 mm or more and 8 mm or less, more preferably 4 mm or more and 6 mm or less. In this embodiment, the gap S1 is open only on the side connected to the support 35, but this is not limited to this. For example, as shown in FIG. 7A and FIG. 7B, by disposing plural gas flow channels 38 on the circumference through which inert gas flows from the side surface of the insulating cover 36 to the gap S1, the intrusion of carbide-containing gas can be more effectively prevented. The width b of the flow channel a1 is, for example, 1 mm or more and 2 mm or less, more preferably 1.3 mm or more and 1.7 mm or less.

FIG. 4 is a graph showing the relationship between the accumulated film thickness of carbide adhered to the surface of the insulating cover 36 and the secondary leakage current, depending on whether or not the gap S1 lies between the power-feeding rod 33 and the insulating cover 36.

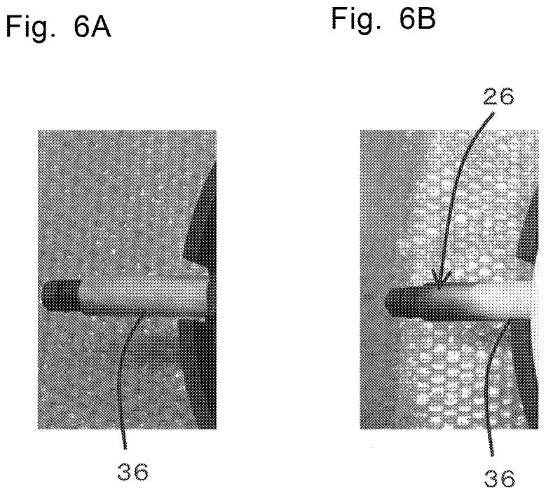

As shown in FIG. 4, when there is no gap between the power-feeding rod 33 and the insulating cover 36, the secondary leakage current increases rapidly when the accumulated film thickness of carbide adhered to the surface of the insulating cover 36 exceeds a certain thickness. This indicates that the carbide forms a current path to the first thermal insulator 30 shown in FIG. 6, causing leakage current.

On the other hand, the Group III compound semiconductor crystal producing apparatus 1 according to the first embodiment, the gap S1 is disposed between the power-feeding rod 33 and the insulating cover 36. In this case, no change is observed in the secondary leakage current even if the accumulated film thickness of carbide adhered to the surface of the insulating cover 36 increases. In other words, by disposing a gap S3 between the power-feeding rod 33 and the insulating cover 36, a current path is not formed between the power-feeding rod 33 and carbide adhered to the surface of the insulating cover 36.

### Second Embodiment

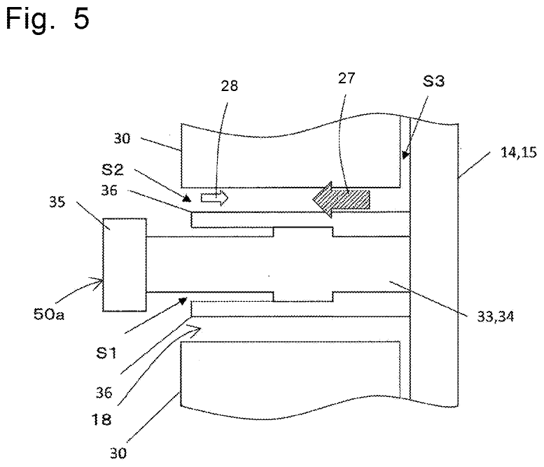

FIG. 5 is a schematic cross-sectional view showing the cross-sectional structure of a power-feeding section 50a in a Group III compound semiconductor crystal producing apparatus according to the second embodiment.

As shown in FIG. 5, the power-feeding section 50a in the Group III compound semiconductor crystal producing apparatus according to the second embodiment is characterized in that the flow channel (third gap) S3 through which an inert gas 27 flows is disposed between the first heater 14, the second heater 15, and the first thermal insulator 30. The inert gas 27 flows from the upper part of the source material reaction chamber 1 through the third gap S3, enters the second gap S2 via the first through-hole 18, and flows toward the support 35. The inert gas 27 may be, for example, Ar or N₂. On the other hand, as shown in FIG. 5, a carbide-containing gas 28 flows from the support 35 into the first through-hole 18, causing carbide to adhere to the insulating cover 36. Thus, in order to suppress the inflow of the carbide-containing gas 28 into the first through-hole 18, it is desirable that the flow velocity of inert gas 27 minus the flow velocity of the carbide-containing gas flowing from the support 35 into the first through-hole 18 be a positive value. Specifically, the flow velocity of the inert gas that is effective in suppressing the adhesion of carbide is, for example, 1.5 m/s or more and 3 m/s or less, more preferably 1.8 m/s or more and 2.2 m/s or less. This makes it possible to suppress the inflow of the carbide-containing gas 28 into the first through-hole 18, suppress the adhesion of carbide to the insulating cover 36, and suppress current leakage from the power-feeding rod 33.

FIGS. 6A and 6B show the difference in carbide adhesion to the insulating cover when the flow velocity, obtained by subtracting the flow velocity of the carbide-containing gas flowing from the support into the first through-hole from the inert gas flow velocity, is 2.0 m/s (FIGS. 6A) and 0.5 m/s (FIG. 6B).

As shown in FIG. 6A, when the flow velocity obtained by subtracting the flow velocity of the carbide-containing gas flowing from the support into the first through-hole from the inert gas flow velocity is 2.0 m/s, almost no carbide adheres to the insulating cover 36. On the other hand, as shown in FIG. 6B, when the flow velocity obtained by subtracting the flow velocity of the carbide-containing gas flowing from the support into the first through-hole from the inert gas flow velocity is 0.5 m/s, carbide 26 adheres to a part of the insulating cover 36.

### Third Embodiment

FIG. 7A is a schematic cross-sectional view showing the cross-sectional structure of a power-feeding section 50b in a Group III compound semiconductor crystal producing apparatus according to a third embodiment, FIG. 7B is a schematic cross-sectional view taken along line A-A in FIG. 7A, and FIG. 7C is a schematic cross-sectional view taken along line B-B in FIG. 7A.

The power-feeding section 50b in the Group III compound semiconductor crystal producing apparatus according to the third embodiment includes a gas supply aperture 37 through which inert gas can be introduced, on the first heater 14 side, into the insulating cover 36. Also, as shown in FIG. 7A and FIG. 7B, the gas flow channel 38 is disposed on the inside of the insulating cover 36 that faces the power-feeding rod 33.

Inert gas introduced through the third gap S3 can be guided to the first gap S1 between the insulating cover 36 and the power-feeding rod 33 via the gas supply aperture 37 and the gas flow channel 38 as shown in FIGS. 7A to 7C. This makes it possible to prevent gas containing carbides from flowing into the first gap S1 between the insulating cover 36 and the power-feeding rod 33, thereby suppressing current leakage from the power-feeding rod 33.

### Fourth Embodiment

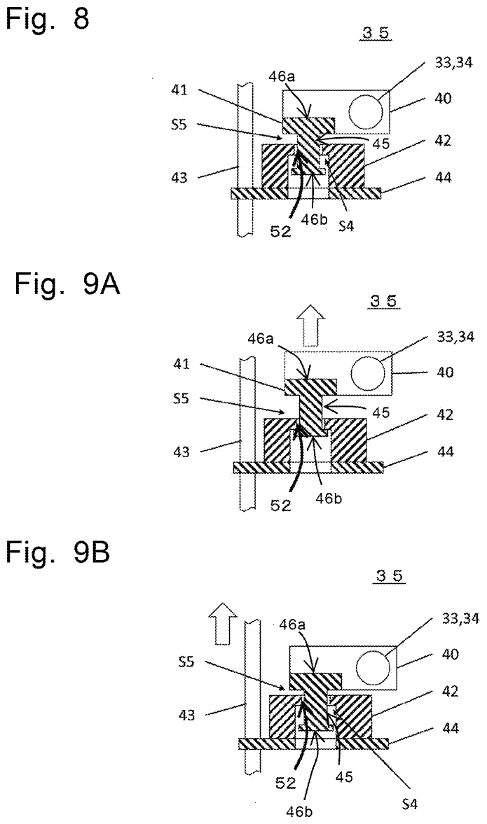

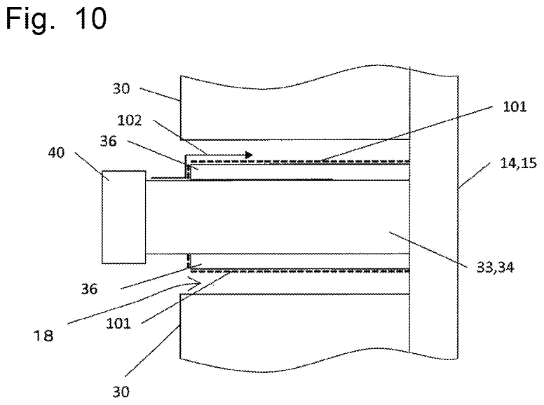

FIG. 8 is a schematic cross-sectional view showing an example of the configuration of the support 35 in a Group III compound semiconductor crystal producing apparatus according to a fourth embodiment. FIG. 9A is a schematic cross-sectional view showing a state in which the first heater has expanded and moved vertically upward in the Group III compound semiconductor crystal producing apparatus of FIG. 8. FIG. 9B is a schematic cross-sectional view showing a state in which the supporting column has expanded and moved vertically upward in the Group III compound semiconductor crystal producing apparatus of FIG. 8.

As shown in FIG. 8, the support 35 includes the connection section 40, electrical insulation sections 42 and 44 that support the connection section 40, and a supporting column 43 to which the electrical insulation sections 42 and 44 are fixed. The power-feeding rod 33 is physically connected to the connection section 40. The connection section 40 includes a stopper 41 that slides through a second through-hole 52 disposed in the electrical insulation section 42. The electrical insulation sections 42 and 44 may be configured as two separate parts, and the electrical insulation section 42 may be connected to the supporting column 43 via a base 44 serving as an electric insulation section. Power is supplied to the power-feeding rod 33 via the connection section 40. The connection section 40 connects the power-feeding rod 33, the stopper 41, and an external power feeder. The connection section 40 can be made of, for example, nickel, iron, stainless steel, copper, aluminum, gold, silver, or an alloy containing any of these as its main components.

The electrical insulation section 42 has a stepped second through-hole 52 extending in the vertical direction, through which the stopper 41 slides. The stopper 41 has middle body 45, upper tab 46a and lower tab 46b (upper and lower tabs). The middle body 45 is slidable along the second through-hole 52 disposed in the electrical insulation section 42. The upper and lower tabs 46a, 46b are provided at both ends of the middle body 45. The middle body 45 is disposed into the second through-hole 52, and the upper and lower tabs 46a, 46b are respectively disposed at the top and bottom of the second through-hole 52 to prevent the stopper 41 from coming off the second through-hole 52 of the electrical insulation section 42. In the fourth embodiment, the stopper 41 has a stepped cylindrical shape. However, the stopper 41 including the middle body 45, upper and lower tabs 46a, 46b may have other shapes, such as stepped rectangular columns, that each of the upper and lower tabs 46a, 46b may have a cross-section larger than the cross-section of the second through-hole 52 at the top opening and bottom opening of the second through-hole 52. Then, a range in which the stopper 41 slides through the top opening and the bottom opening of the second through-hole 52 may be defined. The stopper 41, the base 44, and the supporting column 43 may be made of, for example, iron or an iron-based alloy such as SUS. The electrical insulation section 42 has electrical insulating properties to prevent current leakage from the stopper 41 and the connection section 40 to the outside via the base 44 and the supporting column 43. Examples of materials that can be used for the electrical insulation section 42 include alumina, quartz, PEEK, and PTFE.

A fourth gap S4 is disposed between the lower return of the stopper 41 and the undersurface of the electrical insulation section 42, and a fifth gap S5 is disposed between the upper return of the stopper 41 and the upper surface of the electrical insulation section 42.

As shown in FIG. 9A, when the thermal expansion of the first heater 14 and second heater 15 is large, the stopper 41 slides vertically upward in a direction that fills the fourth gap S4. On the other hand, as shown in FIG. 9B, when the thermal expansion of the supporting column 43 is large, the stopper 41 slides vertically downward in a manner that lifts the electrical insulation section 42 in a direction that fills the fifth gap S5. There are no particular limitations on the fourth gap S4 and the fifth gap S5, but they are preferably 2 mm or more and 8 mm or less, and more preferably 4 mm or more and 6 mm or less.

The above-described structure of the support 35 makes it possible to reduce tilt of the power-feeding rod 33 due to a difference in thermal expansion between the first heater 14 and the second heater 15 and the support 35, which occurs when the first heater 14 and the second heater 15 are heated. Keeping the tilt of the power-feeding rod 33 maintains the first gap S1, thereby suppressing current leakage from the power-feeding rod 33. Keeping the tilt of the power-feeding rod 33 also maintains the flow of inert gas. When inert gas is circulated through the second gap S2 as in the second embodiment, the second gap S2 can be maintained, thereby suppressing the adhesion of carbide to the insulating cover 36 and suppressing current leakage from the power-feeding rod 33.

Furthermore, when inert gas is circulated through the first gap S2 as in the second embodiment, the first gap S1 can be maintained, thereby suppressing inflow of gas containing carbides into the first gap S1 and suppressing current leakage from the power-feeding rod 33.

### REFERENCE SIGNS LIST

1 Group III compound semiconductor crystal producing apparatus
2 Source reaction chamber
3 Source vessel
4 Starting Ga source
5 Source reaction section
6 Crystal growth section
7 Reactive gas supply pipe
8 Source gas nozzle
9 Reactive gas nozzle
10 Gas flow channel
11 Seed substrate
12 Substrate holding member
13 Rotating shaft
14 First heater
15 Second heater
16 Heating section
17 Discharge port
18 First through-hole
20 Reaction vessel
22 Injection port
24 Imaginary line
25 Imaginary line
26 Carbide
27 Inert gas
28 Carbide-containing gas
30 First thermal insulator
31 Second thermal insulator
32 Third thermal insulator
33, 34 Power-feeding rod
35 Support for supporting Power-feeding rod
36 Insulating cover for Power-feeding rod
37 Gas supply aperture
38 Gas flow channel
40 Connection section for Power-feeding rod
41 Stopper
42 Electrical Insulation section
43 Supporting column
44 Base
45 Middle Body
46a Upper Tab
46b Lower Tab
50 Power-feeding section
52 Second through-hole
101 Carbon coating layer
102 Current path

What is claimed is

1. A Group III compound semiconductor crystal producing apparatus for producing a Group III compound semiconductor crystal, comprising a reaction vessel,
wherein the reaction vessel comprises:
a heating section that heats the reaction vessel;
a thermal insulation section that thermally insulates the heating section from the outside; and
a power-feeding section that supplies power to the heating section,
wherein the thermal insulation section includes a first thermal insulator arranged to surround an outer periphery of the heating section,
wherein the power-feeding section includes:
a power-feeding rod disposed inside a first through-hole of the first thermal insulator that opens toward the heating section, the first through-hole being defined by through-hole walls of the first thermal insulator;
an insulating cover for covering the power-feeding rod disposed surrounding the power-feeding rod; and
a support for supporting the power-feeding rod disposed outside the first thermal insulator and physically supporting the power-feeding rod, and
wherein the insulating cover has a first gap between the insulating cover and the power-feeding rod, and a second gap between the insulating cover and the first through-hole of the first thermal insulator,
the first gap being opened toward the support of the power-feeding section, and
the second gap being defined along the first through-hole.

2. The Group III compound semiconductor crystal producing apparatus according to claim 1,
wherein the second gap allows inert gas to flow from the heating section toward the support.

3. The Group III compound semiconductor crystal producing apparatus according to claim 1,
wherein the support for supporting the power-feeding rod includes:
a connection section physically connected to the power-feeding rod;
an electrical insulation section supporting the connection section; and
a supporting column fixing the electrical insulation section,
wherein the connection section includes a stopper that is slidable in a second through-hole disposed in the electrical insulation section,
wherein the stopper has:
a middle body that is slidable along the second through-hole disposed in the electrical insulation section, and
upper and lower tabs provided at both ends of the middle body, each having a cross section greater than the cross section of the second through-hole at the top opening and bottom opening of the second through-hole so as to define a range in which the stopper slides through the second through-hole, and
wherein the stopper has a third gap between the lower tab and an undersurface of the electrical insulation section around the bottom opening, and a fourth gap between the upper tab and an upper surface of the electrical insulation section around the top opening.

4. The Group III compound semiconductor crystal producing apparatus according to claim 1, further comprising:
a plurality of flow channels through which inert gas is flowable from a side surface of the insulating cover to the first gap between the insulating cover and the power-feeding rod.
